(19) United States
(12) Patent Application Publication
(10) Pub. No.: US 2009/0159888 A1
(43) Pub. Date: Jun. 25, 2009

(54) DISPLAY PANEL AND METHOD FOR MANUFACTURING THE SAME

(75) Inventors: Jung-In PARK, Suwon-si (KR); Woo-Seok JEON, Seongnam-si (KR)

Correspondence Address: CANTOR COLBURN, LLP, 20 Church Street, 22nd Floor, Hartford, CT, 06103, US

(73) Assignee: SAMSUNG ELECTRONICS CO., LTD, Suwon-si (KR)

(21) Appl. No.: 12/203,427

(22) Filed: Sep. 3, 2008

(30) Foreign Application Priority Data
Dec. 24, 2007 (KR) 10-2007-0136508

(51) Int. Cl. H01L 29/04; H01L 21/336; H01L 21/44

(52) U.S. Cl. 257/59; 438/158; 438/669; 257/E29.003; 257/E21.476; 257/E21.414

(57) ABSTRACT

A display panel and a manufacturing method thereof which includes forming a color filter on an insulating substrate, forming a plurality of trenches in the color filter, forming a first metal layer in the trenches, forming a second metal layer on the first metal layer to form gate lines, forming a gate insulating layer on the color filter and the gate lines, forming a semiconductor on the gate insulating layer, forming data lines including source electrodes and drain electrodes, and forming pixel electrodes connected to the drain electrodes.

This application claims priority to Korean Patent Application No. 10-2007-0136508 filed on Dec. 24, 2007, and all of the benefits accruing therefrom under 35 U.S.C. §119, the contents of which in its entirety is herein incorporated by reference.

### BACKGROUND OF THE INVENTION

1. Field of the Invention

The present invention relates to a display panel and a manufacturing method thereof.

2. Description of the Related Art

A liquid crystal display (“LCD”), a plasma display panel (“PDP”), and an organic light emitting diode (“OLED”) display are among widely used flat panel displays.

These conventional display devices include a switching element connected to a field generating electrode, and a plurality of signal lines including a gate line and a data line to apply voltages to the field generating electrode by controlling the switching element. To reduce a sticking image of the display device and to improve the resolution, it is preferable that the resistance of the signal lines is low.

Due to the increasing of the size of the display devices, a more improved response speed is required to obtain high quality, and research to reduce the resistance of the signal lines has actively progressed.

For a signal line with low resistance, a conventional method in which a low resistance metal such as aluminum (Al), copper (Cu), and silver (Ag) is deposited and patterned by photolithography is used, but the low resistance metal includes a poor adhesion characteristic with a glass substrate and may be diffused into a lower layer or an upper layer such that the reliability that the low metal is adapted to the actual process is decreased. Also, additional processes are required to compensate this problem.

### BRIEF SUMMARY OF THE INVENTION

The present invention has been made in an effort to solve the above-stated problems and aspects of the present invention provide a display panel and manufacturing method to simplify the manufacturing process while simultaneously obtaining low resistance and reliability.

In an exemplary embodiment, the present invention provides a display panel including a substrate, a color filter formed on the substrate and including a plurality of trenches, a gate line formed in each trench of the color filter and between neighboring different color filters, a data line which intersects the gate line and transmits data voltages, a thin film transistor connected to the gate and data lines, and a pixel electrode connected to the thin film transistor.

According to an exemplary embodiment, the gate line includes a first layer including copper (Cu) or silver (Ag).

According to an exemplary embodiment, the gate line further includes a second layer formed under the first layer and including a seed metal.

According to an exemplary embodiment, the seed metal includes at least one of molybdenum (Mo), nickel (Ni), titanium (Ti), chrome (Cr), tantalum (Ta) and tungsten (W).

According to an exemplary embodiment, the first layer is thicker than the second layer.

According to an exemplary embodiment, the seed metal includes at least one of indium tin oxide (ITO), tin oxide (SnO2), zinc oxide (ZnO), and titanium oxide (TiO).

According to an exemplary embodiment, the thickness of the gate line is in a range of approximately 1 to approximately 4 μm.

In another exemplary embodiment, the present invention provides a display panel including a gate line including a gate electrode, a color filter which encloses the gate line and formed on a same level with the gate line, a gate insulating layer formed on the gate line and the color filter, a semiconductor formed on the gate insulating layer and overlapping the gate electrode, a source electrode and a drain electrode opposite to each other on the semiconductor, a data line connected to the source electrode, and a pixel electrode connected to the drain electrode.

According to an exemplary embodiment, the color filter includes a plurality of trenches, and a gate line is disposed in each trench of the color filter.

According to an exemplary embodiment, the gate line includes a gate pad for connection with an external circuit, and the gate pad is disposed in each trench of the color filter.

According to an exemplary embodiment, the gate line includes a first layer including one of copper (Cu) or silver (Ag).

According to an exemplary embodiment, the gate line further includes a second layer disposed under the first layer and including a seed metal.

According to an exemplary embodiment, the seed metal includes at least one of molybdenum (Mo), nickel (Ni), titanium (Ti), chrome (Cr), tantalum (Ta) and tungsten (W).

According to an exemplary embodiment, the seed metal includes at least one of indium tin oxide (ITO), tin oxide (SnO2), zinc oxide (ZnO), and titanium oxide TiO).

In another exemplary embodiment, the present invention provides a manufacturing method, the method including forming a color filter on a substrate, forming a plurality of trenches in the color filter, forming a first metal layer in the trenches, forming a second metal layer on the first metal layer to form a gate line, forming a gate insulating layer on the color filter and the gate line, forming a semiconductor on the gate insulating layer, forming a data line including a source electrode and a drain electrode, and forming a pixel electrode connected to the drain electrode.

According to an exemplary embodiment, forming of the second metal layer by electroless plating.

According to an exemplary embodiment, a same mask is used in forming the trenches in the color filter and forming the first metal layer in the trench. Further, according to an exemplary embodiment, the color filter and the first metal layer are respectively patterned.

According to an exemplary embodiment, the second metal layer includes one of copper (Cu) or silver (Ag).

According to an exemplary embodiment, the first metal layer includes at least one of molybdenum (Mo), nickel (Ni), titanium (Ti), chrome (Cr), tantalum (Ta) and tungsten (W).

In another exemplary embodiment, the present invention provides a manufacturing method including forming a color filter on a substrate, forming a plurality of trenches in the color filter, and forming a signal line in each trench of the color filter, wherein the forming of the signal line includes depositing a first metal layer on a total surface of the color filter, patterning the first metal layer such that the first metal layer remains in each trench, and forming a second metal layer on the patterned first metal layer by electroless plating.

According to an exemplary embodiment, the same mask is used in forming the trenches in the color filter and forming the first metal layer in the trenches.

According to an exemplary embodiment, the first metal layer includes at least one of molybdenum (Mo), nickel (Ni), titanium (Ti), chrome (Cr), tantalum (Ta) and tungsten (W) and the second metal layer includes one of copper (Cu) and silver (Ag).

According to an exemplary embodiment, the gate line is made of a low resistance metal such as copper, silver, or alloys thereof and is of a thickness such that the resistance may be reduced in a display panel of a large size and the signal delay may be prevented.

Also, when forming the gate line to be of a specific thickness, conventional photolithography is not used instead an electroless plating process using the seed metal layer is used such that adhesion deterioration with the substrate may be prevented.

Furthermore, when forming the gate line, according to an exemplary embodiment, the color filter is used as a mold in the electroless plating such that an additional mold may be eliminated to thereby simplify the manufacturing process and reduce the manufacturing cost.

Also, according to an exemplary embodiment, the thickness of the gate line is controlled according to the thickness of the color filter or the depth of the trench of the color filter such that the thickness thereof may be easily controlled.

Furthermore, according to an exemplary embodiment, a same mask is used in forming the trenches in the color filters and patterning the seed metal layer such that the number of masks may be reduced.

### BRIEF DESCRIPTION OF THE DRAWINGS

The above and/or other aspects, features, and advantages of the present invention will become more apparent from the following detailed description when taken in conjunction with the accompanying drawings, in which:

FIG. 1 is a layout view of an exemplary embodiment of a thin film transistor array panel according to the present invention.

FIG. 2 and FIG. 3 are cross-sectional views of the thin film transistor array panel of FIG. 1 taken along with the line II-II and III-III.

FIG. 4, FIG. 6, FIG. 13, FIG. 15, and FIG. 17 are layout views of a thin film transistor array panel in an intermediate process of manufacturing the thin film transistor array panel of FIG. 1 through FIG. 3, according to an exemplary embodiment of the present invention.

FIG. 5 is a cross-sectional view of the display panel shown in FIG. 4 taken along the line V-V.

FIG. 7 is a cross-sectional view of the display panel shown in FIG. 6 taken along the line VII-VII.

FIG. 8 through FIG. 12 are cross-sectional views of an exemplary embodiment of operations following those operations of FIG. 6 and FIG. 7 in the manufacturing method,

FIG. 14 is a cross-sectional view of the display panel shown in FIG. 13 taken along the line XIV-XIV,

FIG. 16 is a cross-sectional view of the display panel shown in FIG. 15 taken along the line XVI-XVI,

FIG. 18 is a cross-sectional view of the display panel shown in FIG. 17 taken along the line XVIII-XVIII.

### DETAILED DESCRIPTION OF THE INVENTION

The invention is described more fully hereinafter with reference to the accompanying drawings, in which exemplary embodiments of the invention are shown. The present invention may, however, be embodied in many different forms and should not be construed as being limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

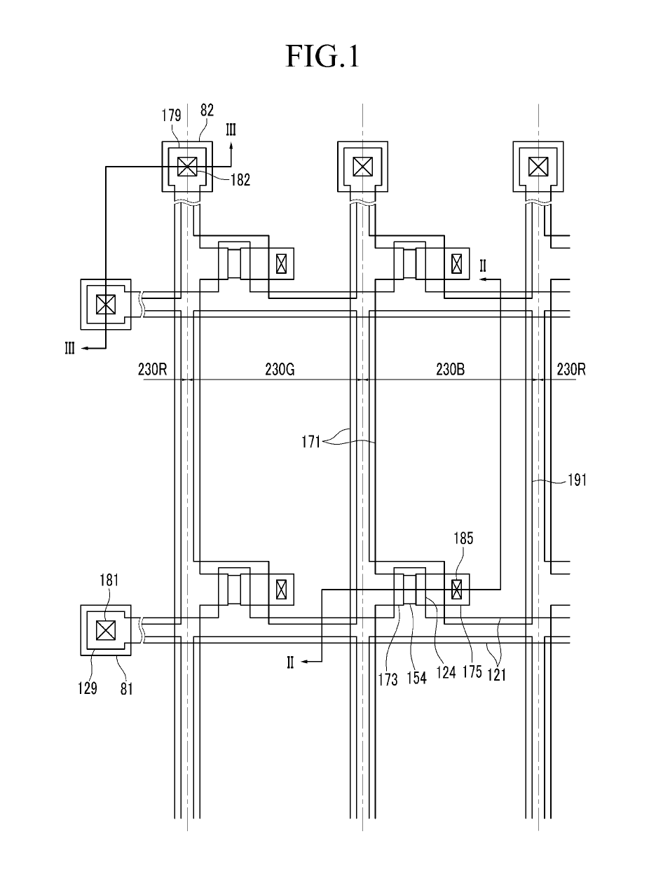

Now, a structure of a thin film transistor array panel according to an exemplary embodiment of the present invention will be described in detail with reference to FIG. 1 through FIG. 3.

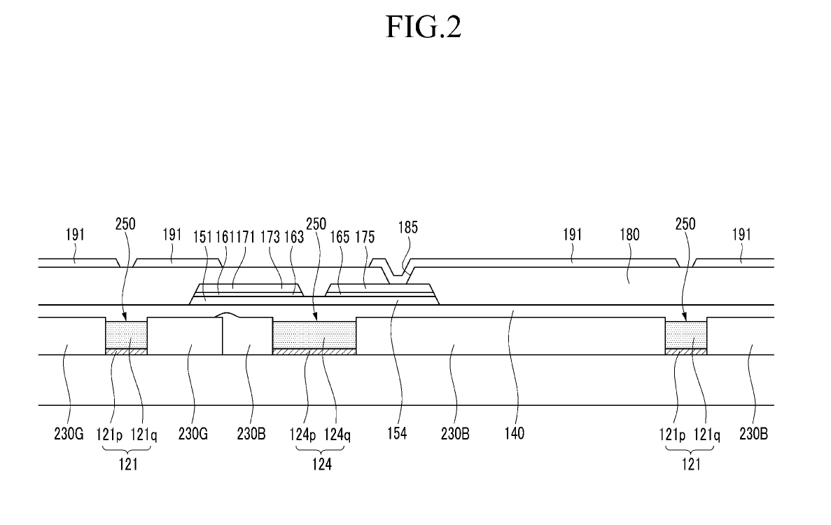

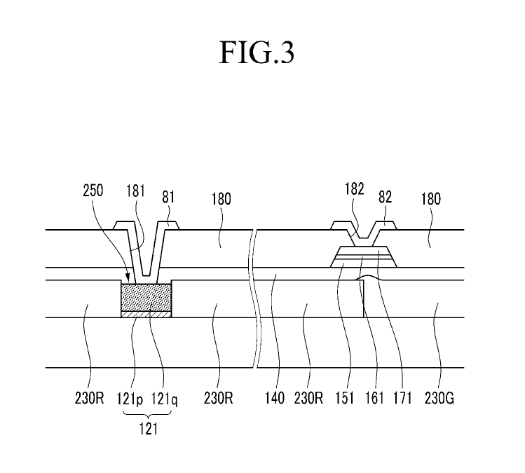

FIG. 1 is a layout view of a thin film transistor array panel according to an exemplary embodiment of the present invention, and FIG. 2 and FIG. 3 are cross-sectional views of the thin film transistor array panel of FIG. 1 respectively taken along the lines II and III-III.

According to an exemplary embodiment, a plurality of color filters 230R, 230G, and 230B are formed on an insulating substrate 110 made of transparent glass or plastic.

Each color filter 230R, 230G and 230B is a stripe type of which the red filter 230R, the green filter 230G, and the blue filter 230B extend according to a column direction in a line. Alternatively, according to another exemplary embodiment, the red filter 230R, the green filter 230G, and the blue filter 230B are alternately arranged in each pixel. Further, according to an exemplary embodiment, the edges of the neighboring color filters 230R, 230G, and 230B overlap each other.

According to an exemplary embodiment, a plurality of trenches 250 (see FIG. 2, for example) are formed in the color filters 230R, 230G, and 230B. The trenches 250 include a plurality of linear portions extending in a horizontal direction, a protruding portion extended from the linear portions, and an end portion disposed at the end of the linear portions and having a wide width.

A plurality of gate lines 121 are formed in the trenches 250. Thus, the trenches 250 and the gate lines 121 substantially have a same planer shape.

The gate lines 121 transmit gate signals and substantially extend in a horizontal direction. Each of the gate lines 121 includes a plurality of gate electrodes 124 projecting upward and a gate pad 129 having a large area for contact with an external driving circuit (not shown). Among the gate lines 121, a portion thereof extending in the horizontal direction, the portion of the gate electrodes 124, and the gate pad 129 are disposed on the linear portions, the protruding portion, and the end portion of each trench 250.

According to an exemplary embodiment, the gate lines 121 include an upper layer 121q, 124q, and 129q made of a low resistance metal such as copper (Cu), silver (Ag), or an alloy thereof, and a lower layer 121p, 124p, and 129p made of a seed metal on which grow copper (Cu), silver (Ag) or an alloy thereof is grown. For example, the seed metal is one of molybdenum (Mo), nickel (Ni), titanium (Ti), chrome (Cr), tantalum (Ta), tungsten (W) and alloys thereof or the seed metal is one of indium tin oxide (ITO), tin oxide (SnO2), zinc oxide (ZnO), titanium oxide (TiO) and alloys thereof.

The thickness of the gate lines 121 may be in the range of approximately from 1 to 4 μm, and the upper layers 121q, 124q, and 129q are thicker than the lower layers 121p, 124p, and 129p. For example, according to an exemplary embodiment, the thickness of the lower layers 121p, 124p, and 129p is larger than approximately 300 Å, and the thickness of a remaining portion may be the upper layer 121q, 124q, and 129q.

The gate lines 121 are formed in the trenches 250 of the color filters 230R, 230G, and 230B such that they are enclosed by the color filters 230R, 230G, and 230B. The color filters 230R, 230G, and 230B formed on a same level with the gate lines 121. In the current exemplary embodiment, the gate lines 121 directly contact the color filters 230R, 230G, and 230B at a side thereof, or alternatively are separated therefrom by a predetermined interval considering a process margin.

According to an exemplary embodiment, a gate insulating layer 140 is formed on the gate lines 121.

According to an exemplary embodiment, a plurality of semiconductor stripes 151 made of amorphous silicon or polycrystalline silicon are formed on the gate insulating layer 140 in a vertical direction. The semiconductor stripes 151 include a plurality of protrusions 154 extended toward the gate electrodes 124.

According to an exemplary embodiment, a plurality of ohmic contact stripes 161 and a plurality of ohmic contact islands 165 are formed on the semiconductor stripes 151. According to an exemplary embodiment, the ohmic contact stripes 161 and the ohmic contact islands 165 are made of n+ hydrogenated a—Si heavily doped with an N-type impurity such as phosphorous, or they may be made of silicide. The ohmic contact stripes 161 include a plurality of protrusions 163 extended toward the protrusions 154 of the semiconductor stripes 151, and the protrusions 163 and the ohmic contact islands 165 form in a pair and are disposed on the protrusions 154 of the semiconductor stripes 151.

According to an exemplary embodiment, a plurality of data lines 171 and a plurality of drain electrodes 175 are formed on the ohmic contact stripes 161, the ohmic contact islands 165, and the gate insulating layer 140.

The data lines 171 transmit data voltages extend in a vertical direction and intersect the gate lines 121. Each of the data lines 171 includes a plurality of source electrodes 173 extending toward the gate electrodes 124, and a data pad 179 having a wide area for connection with other layers or an external driving circuit (not shown).

The drain electrodes 175 are separated from the data lines 171 and are opposite to the source electrodes 173 based on the gate electrodes 124.

A gate electrode 124, a source electrode 173, and a drain electrode 175 form a thin film transistor (“TFT”) along with a protrusion 154 of the semiconductor stripe 151, and the channel of the thin film transistor is formed on the protrusion 154 of the semiconductor between the source electrode 173 and the drain electrode 175.

According to an exemplary embodiment, the semiconductor stripes 151 substantially have a same planer shape as the data lines 171 and the drain electrode 175 except for the channel regions between the source electrodes 173 and the drain electrodes 175.

According to an exemplary embodiment, the ohmic contact stripes 161 substantially have a same planer shape as the data lines 171, and are disposed between the semiconductor stripes 151 and the data lines 171. Further, the ohmic contact islands 165 are disposed between the semiconductor stripes 151 and the drain electrodes 175, and substantially have a same planer shape as the drain electrodes 175.

A passivation layer 180 is formed on the data lines 171 and the drain electrodes 175. The passivation layer 180 includes a plurality of contact holes 185 and 182 exposing the drain electrodes 175 and the data pads 179, respectively, and the passivation layer 180 and the gate insulating layer 140 include a plurality of contact holes 181 respectively exposing the gate pads 129.

According to an exemplary embodiment, a plurality of pixel electrodes 191 and a plurality of contact assistants 81 and 82 are formed on the passivation layer 180.

As shown in FIG. 2, the pixel electrodes 191 are connected to the drain electrodes 175 through the contact holes 185 and receive the data voltages from the drain electrodes 175.

The contact assistants 81 and 82 are connected to the gate pads 129 and the data pads 179 through the contact holes 181 and 182, respectively. The contact assistants 81 and 82 compensate the adhesiveness between the gate pads 129 and the data pads 179 and an external apparatus such as a driver IC, and also to protect the gate pads 129 and the data pads 179.

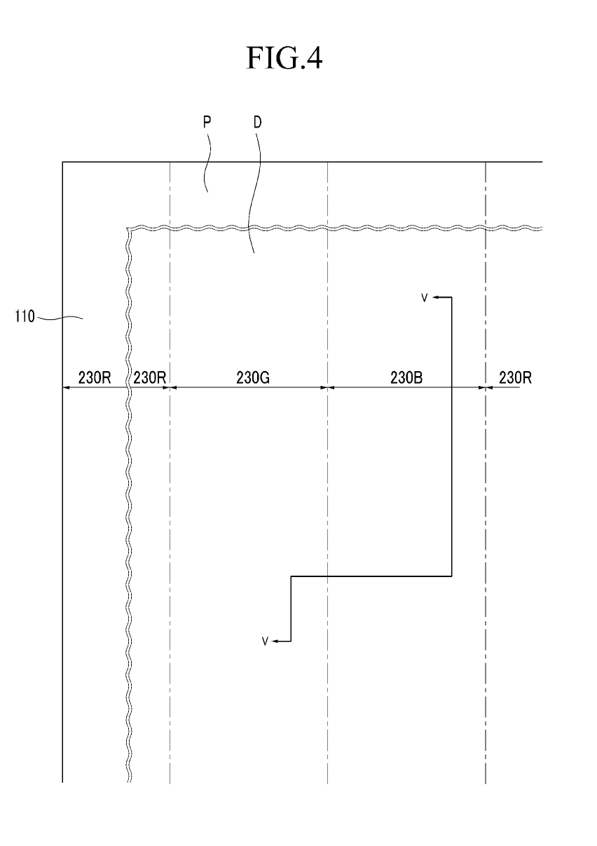

Next, a method for manufacturing a thin film transistor array panel shown in FIG. 1 through FIG. 3 according to an exemplary embodiment of the present invention will be described in detail with reference to FIG. 4 through FIG. 18.

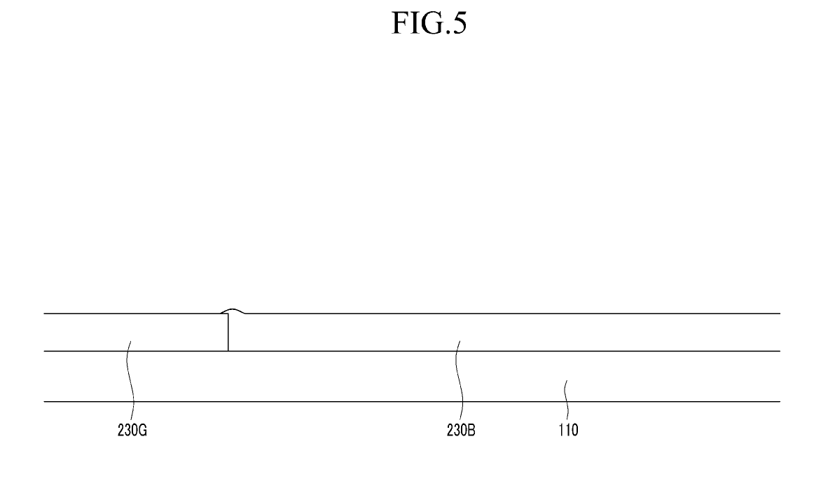

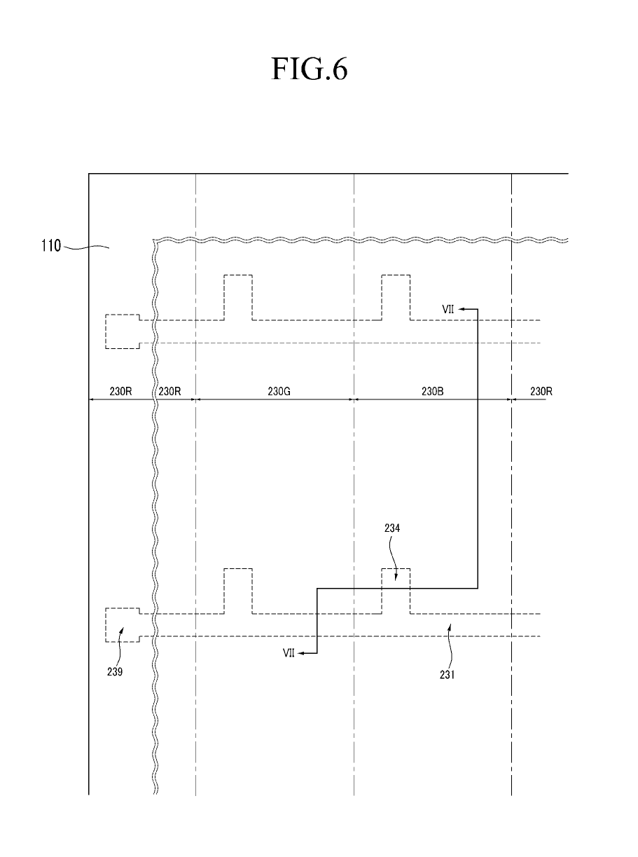

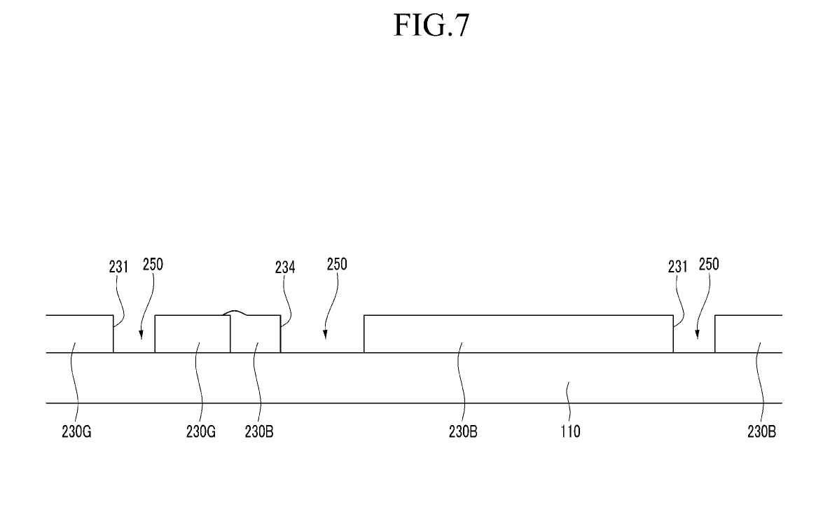

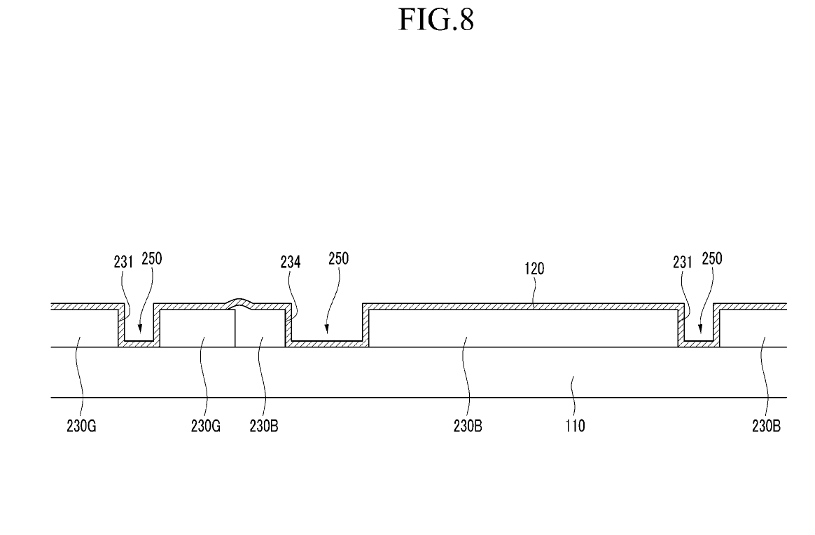

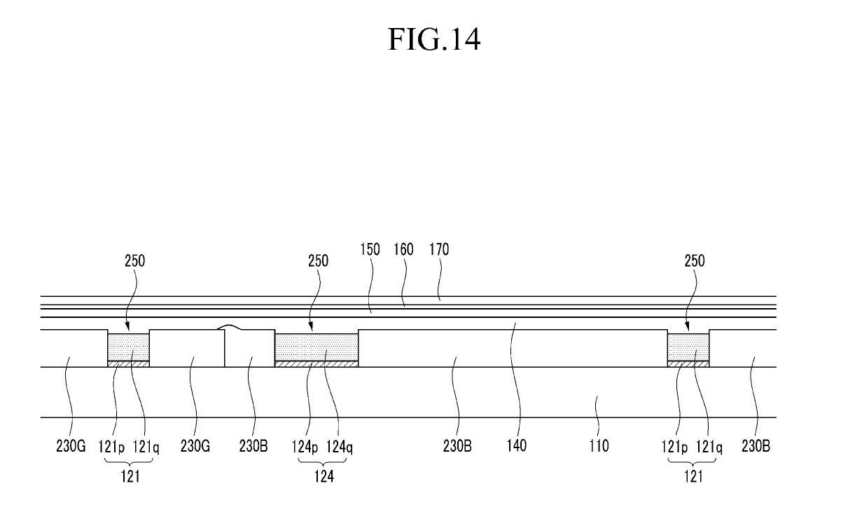

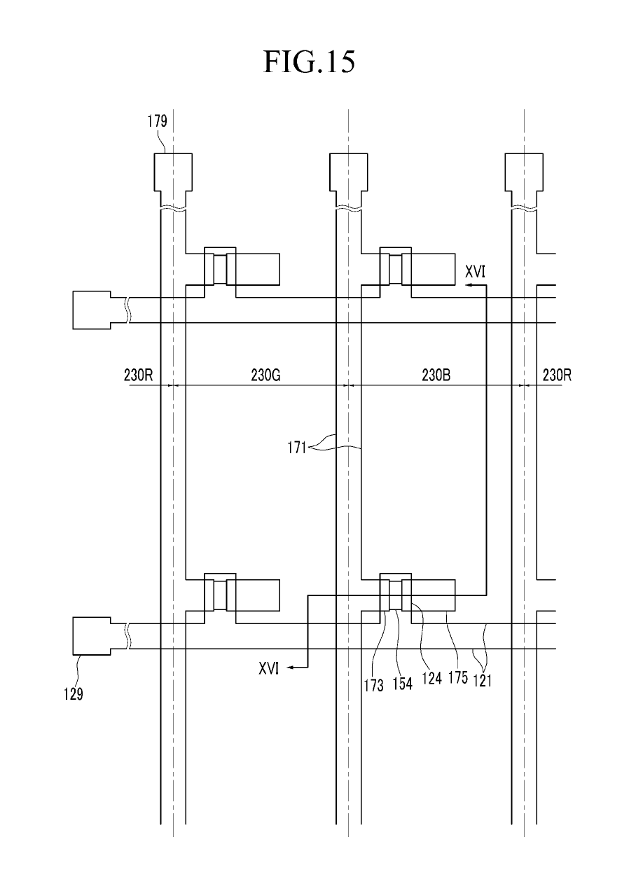

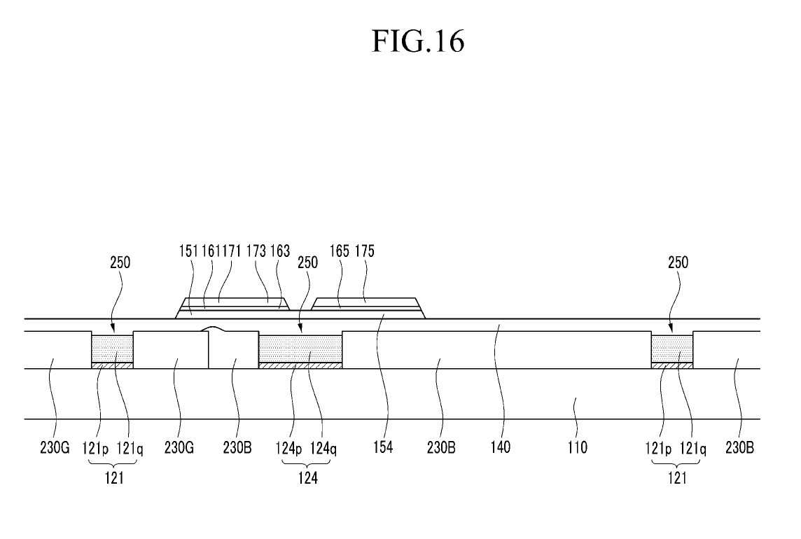

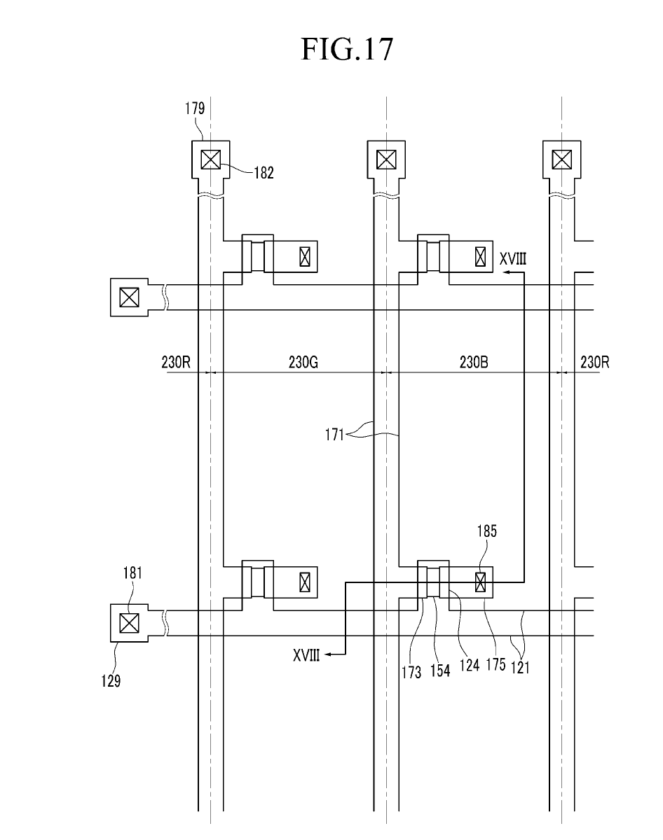

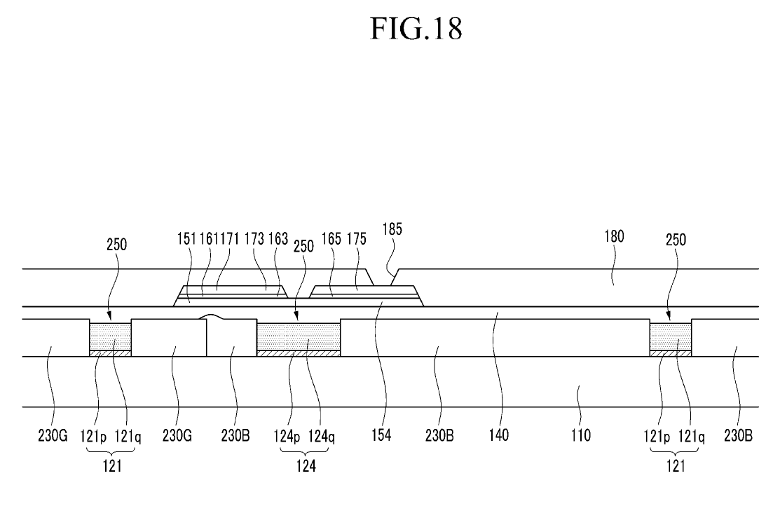

FIG. 4, FIG. 6, FIG. 13, FIG. 15, and FIG. 17 are layout views of a thin film transistor array panel in an intermediate process of manufacturing the thin film transistor array panel of FIG. 1 through FIG. 3 according to an exemplary embodiment of the present invention, FIG. 5 is a cross-sectional view of the display panel shown in FIG. 4 taken along the line V-V, FIG. 7 is a cross-sectional view of the display panel shown in FIG. 6 taken along the line VII-VII, FIG. 8 to FIG. 12 are cross-sectional views showing operations of the manufacturing method following those of FIG. 6 and FIG. 7 in the manufacturing method, FIG. 14 is a cross-sectional view of the display panel shown in FIG. 13 taken along the line XIV-XIV, FIG. 16 is a cross-sectional view of the display panel shown in FIG. 15 taken along the line XVI-XVI, and FIG. 18 is a cross-sectional view of the display panel shown in FIG. 17 taken along the line XVIII-XVIII.

Referring to FIG. 4 and FIG. 5, a plurality of color filters 230R, 230G, and 230B are coated on an insulating substrate 110. For example, according to an exemplary embodiment, the color filters 230R, 230G, and 230B may be formed by a method in which the red filter 230R is coated on a total surface of the insulating substrate 110 and patterned by a photo process, the green filter 230G is coated on the total surface of the insulating substrate 110 and patterned by a photo process, and the blue filter 230B is coated on the total surface of the insulating substrate 110 and patterned by a photolithography process, for example. However, is the present invention is not limited hereto, and an inkjet printing process may be used to form them.

In the current exemplary embodiment, the color filter 230R is also formed in a pad region P where a plurality of pads such as the gate pads 129 and the data pads 179 are disposed, as well as a display region D having a plurality of pixels disposed therein.

Referring to FIG. 6 and FIG. 7, a mask (not shown) is aligned on the color filters 230R, 230G, and 230B, and the color filters 230R, 230G, and 230B are exposed through with light and developed to form a plurality of trenches 250. The trenches 250 include a plurality of linear portions 231 extending in a horizontal direction, a protruding portion 234 extended from the linear portions 231, and an end portion 239 disposed on the end of the linear portions 231 and having a wide width.

Next, referring to FIG. 8, a seed metal layer 120 such as Mo, Ni, Ti, Cr, Ta, or W is formed on the total surface of the color filters 230R, 230G, and 230B having the trenches 250 and on the insulating substrate 110.

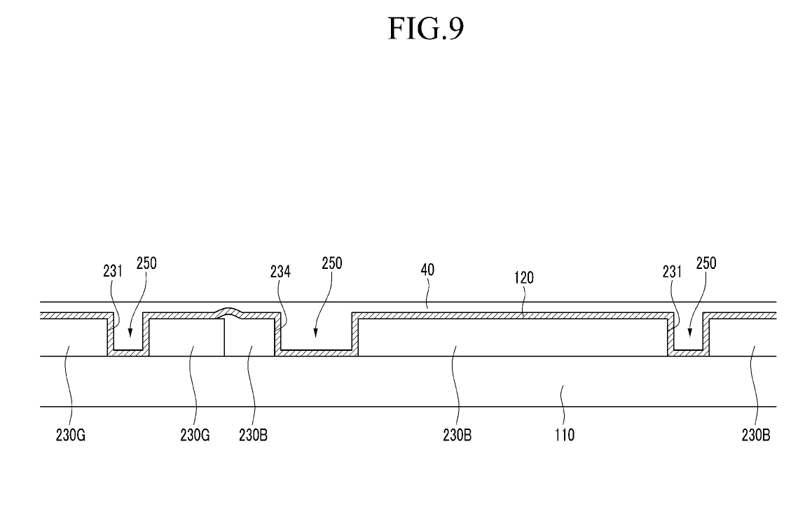

As shown in FIG. 9, according to an exemplary embodiment, a photosensitive film 40 is coated on the seed metal layer 120.

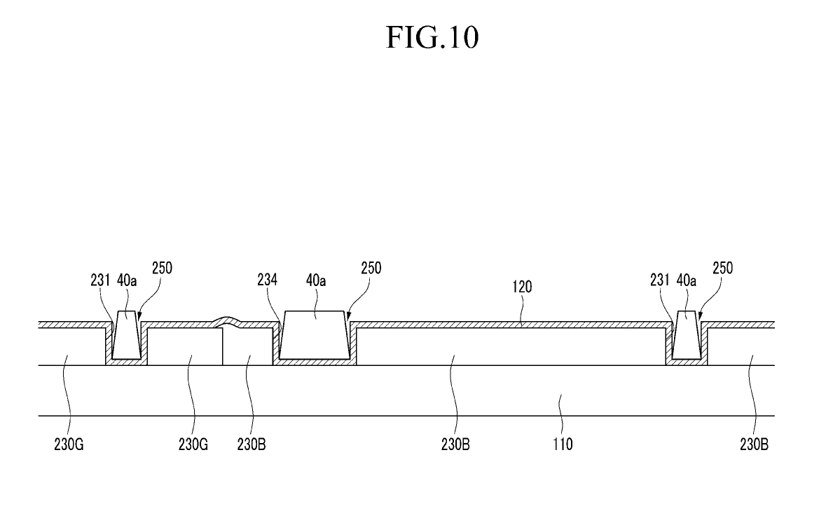

As shown in FIG. 10, according to an exemplary embodiment, a mask (not shown) is aligned on the photosensitive film 40, and the photosensitive film 40 is exposed and developed to form a plurality of photoresist patterns 40a only disposed in the trenches 250.

In the current exemplary embodiment, the same mask may be used when forming the trenches 250 and of patterning the photosensitive film 40. Accordingly, according to the current exemplary embodiment, one mask required in the manufacturing process may be eliminated.

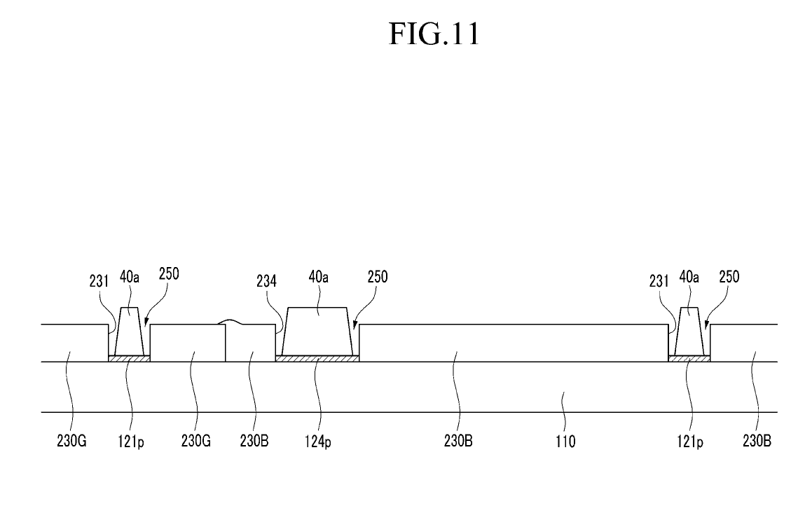

As shown in FIG. 11, the seed metal layer 120 is etched by using the photoresist patterns 40a as an etching mask to only leave the seed metal layer 120 in the trenches 250. Therefore, a lower layer 121p of a gate line, a lower layer 124p of a gate electrode 124, and a lower layer of a gate pad (not shown) are formed from the seed metal layer 120.

According to an exemplary embodiment, the photoresist patterns 40a are removed.

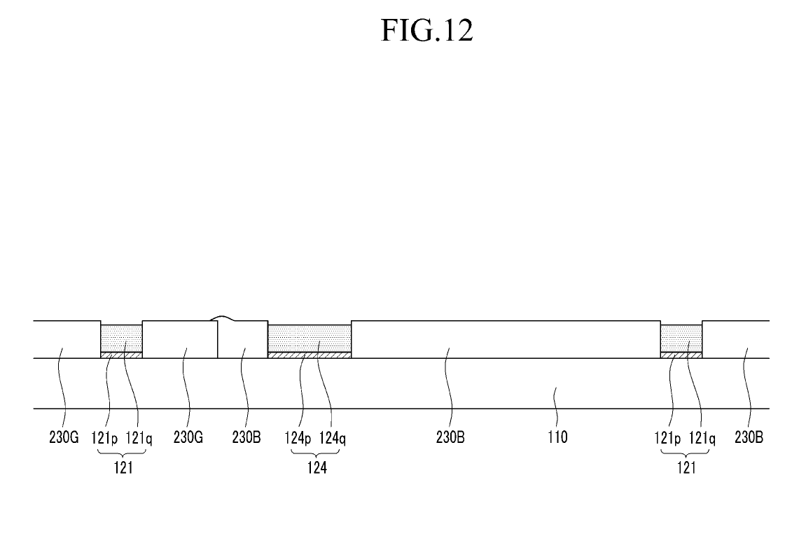

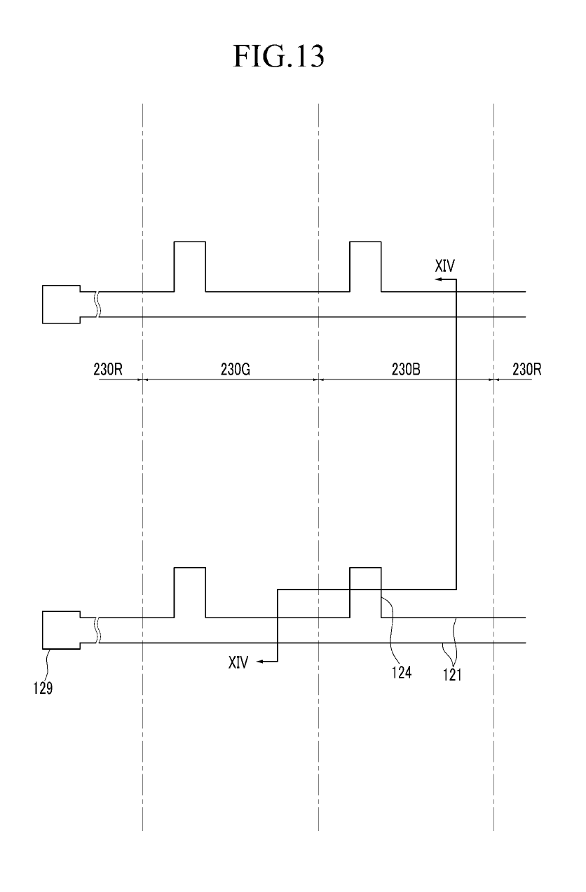

As shown in FIG. 12, electroless plating using an electrolyte solution including a low resistance metal such as Cu or Ag is executed. According to an exemplary embodiment, in the electroless plating, the insulating substrate 110 may be immersed in the electrolyte solution or the electrolyte solution may be sprayed on the insulating substrate 110.

By performing the electroless plating, the Cu, Ag, or the alloy thereof is grown on the lower layers 121p and 124p such that an upper layer 121q of the gate line, an upper layer 124q of the gate electrode, and an upper layer (not shown) of the gate pad 129 are formed.

As shown in FIG. 13 and FIG. 14, a gate insulating layer 140, a semiconductor layer 150, an ohmic contact layer 160, and a data metal layer 170 are sequentially deposited on the gate line 121, and a photosensitive film (not shown) is coated thereon.

According to an exemplary embodiment, a mask (not shown) is aligned on the photosensitive film (not shown), and the photosensitive film is exposed. In the current exemplary embodiment, the mask may include a semi-transmissive region as well as a shielding region and a transmissive region. The semi-transmissive region may have a slit pattern, a lattice pattern, or a thin film(s) with intermediate transmittance or intermediate thickness.

Next, the mask is removed and the exposed photosensitive film is developed to form a photoresist pattern (not shown) having different thicknesses.

The data metal layer 170, the ohmic contact layer 160, and the semiconductor layer 150 are then sequentially etched by using the photoresist pattern as an etching mask.

As shown in FIG. 15 and FIG. 16, an etch-back process such as ashing is performed to remove a portion of the photoresist pattern, and the data metal layer 170 is secondarily etched by using the photoresist pattern as an etching mask to form a plurality of data lines 171 including a plurality of source electrodes 173 and data pads 179, and a plurality of drain electrodes 175.

Then, a back channel etch (“BCE”) process is performed to remove the exposed ohmic contact layer 160 between the source electrode 173 and the drain electrode 175.

As shown in FIG. 17 and FIG. 18, a passivation layer 180 is deposited on the total surface of the insulating substrate 110 and patterned by photolithography to form a plurality of contact holes 185, 181, and 182 respectively exposing the drain electrode 175, the gate pad 129, and the data pad 179.

Referring back to FIG. 1 through FIG. 3, a conductive layer is then formed on the passivation layer 180 and patterned by photolithography and etching to form a plurality of pixel electrodes 191 and a plurality of contact assistants 81 and 82.

Accordingly, in an exemplary embodiment of the present invention, the gate line is made of the low resistance metal such as Cu, Ag, or an alloy thereof to be thick such that the resistance may be reduced in a display panel with a large size, so the signal delay may be prevented.

Also, when forming the gate line to be of a specific thickness, the conventional photolithography is not used and the electroless plating using the seed metal layer is used such that adhesion deterioration with the insulating substrate may be prevented.

Furthermore, when forming the gate line according to an exemplary embodiment of the present invention, the color filter is used as a mold in the electroless plating such that an additional mold may be eliminated to thereby simplify the manufacturing process and reduce the manufacturing cost.

Also, the thickness of the gate line is controlled according to the thickness of the color filter or the depth of the trench of the color filter such that the thickness thereof may be easily controlled.

Furthermore, according to an exemplary embodiment, the same mask may be used when forming the trenches in the color filters and patterning the seed metal layer such that the number of masks may be reduced.

While the present invention has been shown and described with reference to some exemplary embodiments thereof, it should by understood by those of ordinary skill in the art that various changes in form and details may be made therein without departing from the spirit and scope of the present invention as defined by the appended claims.

What is claimed is:

1. A display panel comprising:
a insulating substrate;
a color filter formed on the insulating substrate and comprising a plurality of trenches;
a gate line formed in each of the trenches of the color filter and between neighboring different color filters,
a data line intersecting the gate line and transmits data voltages;
a thin film transistor connected to the gate and the data lines; and
a pixel electrode connected to the thin film transistor.

2. The display panel of claim 1, wherein
the gate line comprises a first layer including copper (Cu) or silver (Ag).

3. The display panel of claim 2, wherein
the gate line further comprises a second layer formed under the first layer and comprising a seed metal.

4. The display panel of claim 3, wherein
the seed metal includes at least one of molybdenum (Mo), nickel (Ni), titanium (Ti), chrome (Cr), tantalum (Ta) and tungsten (W).

5. The display panel of claim 4, wherein
the first layer is thicker than the second layer.

6. The display panel of claim 3, wherein
the seed metal includes at least one of indium tin oxide (ITO), tin oxide (SnO2), zinc oxide (ZnO), and titanium oxide (TiO).

7. The display panel of claim 2, wherein
a thickness of the gate line is in a range of approximately 1 to 4 μm.

8. A display panel comprising:
a gate line comprising a gate electrode, which transmits gate signals;
a color filter enclosing the gate line and formed on a same level with the gate line;
a gate insulating layer formed on the gate line and the color filter;
a semiconductor formed on the gate insulating layer, which overlaps the gate electrode;
a source electrode and a drain electrode opposite to each other on the semiconductor;
a data line connected to the source electrode, which transmits data voltages; and
a pixel electrode connected to the drain electrode.

9. The display panel of claim 8, wherein
the color filter comprises a plurality of trenches, and
a gate line is disposed in each trench of the color filter.

10. The display panel of claim 9, wherein
the gate line includes a gate pad which connects with an external circuit, and
the gate pad is disposed in each trench of the color filter.

11. The display panel of claim 9, wherein
the gate line comprises a first layer including copper (Cu) or silver (Ag).

12. The display panel of claim 11, wherein
the gate line further comprises a second layer disposed under the first layer and comprising a seed metal.

13. The display panel of claim 12, wherein
the seed metal comprises at least one of molybdenum (Mo), nickel (Ni), titanium (Ti), chrome (Cr), tantalum (Ta) and tungsten (W).

14. The display panel of claim 12, wherein
the seed metal includes at least one of indium tin oxide (ITO), tin oxide (SnO2), zinc oxide (ZnO), and titanium oxide (TiO).

15. A method for manufacturing a display panel, the method comprising:
forming a color filter on a substrate;
forming a plurality of trenches in the color filter;
forming a first metal layer in each trench of the color filter;
forming a second metal layer on the first metal layer to form a gate line;
forming a gate insulating layer on the color filter and the gate line;
forming a semiconductor on the gate insulating layer;
forming a data line including a source electrode and a drain electrode; and
forming a pixel electrode connected to the drain electrode.

16. The method of claim 15, forming the second metal layer by
electroless plating.

17. The method of claim 16, wherein
a same mask is used when forming the trenches in the color filter and forming the first metal layer in the trenches, and when the color filter and the first metal layer are respectively patterned.

18. The method of claim 16, wherein
the second metal layer comprises copper (Cu) or silver (Ag).

19. The method of claim 18, wherein
the first metal layer comprises at least one of molybdenum (Mo), nickel (Ni), titanium (Ti) chrome (Cr), tantalum (Ta) and tungsten (W).

20. A method for manufacturing a display panel, the method comprising:
forming a color filter on a substrate;
forming a plurality of trenches in the color filter; and
forming a signal line in each trench of the color filter,
depositing a first metal layer on a total surface of the color filter,
patterning the first metal layer such that the first metal layer remains only in each trench, and
forming a second metal layer on the patterned first metal layer by electroless plating.

21. The method of claim 20, wherein
a same mask is used in forming the trenches in the color filter and forming the first metal layers in the trenches.

22. The method of claim 20, wherein
the first metal layer comprises at least one of molybdenum (Mo), nickel (Ni), titanium (Ti), chrome (Cr), tantalum (Ta) and tungsten (W) and
the second metal layer comprises at least one of from copper (Cu) and silver (Ag).
